(19) United States
(12) Patent Application Publication
(10) Pub. No.: US 2008/0149983 A1
(43) Pub. Date: Jun. 26, 2008

(54) METAL-OXIDE-SEMICONDUCTOR (MOS) VARACTORS AND METHODS OF FORMING MOS VARACTORS

(75) Inventors: Robert Mark Rassel, Colchester, VT (US); Douglas Duane Coolbaugh, Highland, NY (US); Zhong-Xiang He, Essex Junction, VT (US); Ebenezer E. Eshun, Newburgh, NY (US); David S. Collins, Williston, VT (US); Douglas Brian Hershberger, Essex Junction, VT (US)

Correspondence Address: WOOD, HERRON & EVANS, LLP (IBM-BUR), 2700 CAREW TOWER, 441 VINE STREET, CINCINNATI, OH, 45202, US

(73) Assignee: International Business Machines Corporation, Armonk, NY (US)

(21) Appl. No.: 11/613,471

(22) Filed: Dec. 20, 2006

(51) Int. Cl. H01L 29/94; H01L 21/20; H01L 21/336

(52) U.S. Cl. 257/312; 438/379; 257/E29.345; 257/E21.422

(57) ABSTRACT

MOS varactor having an entire accumulation and depletion regime of its CV characteristic curve in one bias regime (negative or positive). The MOS varactor may comprise a gate electrode, a well region of semiconductor material having a first conductivity type (e.g., p-type), contact regions to the well region that comprise heavily doped semiconductor material of the first conductivity type (e.g., p⁺-type), and a Schottky junction formed between the gate and contact regions. The Schottky junction may be formed by spacing the contact regions away from the gate electrode and siliciding the substrate surface. The gate electrode may be formed from semiconductor material of a second conductivity type (e.g., n-type) opposite to the first conductivity type, thus changing the flat band voltage of the MOS varactor and shifting accumulation and depletion regime of the CV characteristic curve in one bias regime, such as the negative bias regime.

### FIELD OF THE INVENTION

The invention relates to device structures and methods and, in particular, to device structures for a metal-oxide-semiconductor varactor and methods of forming such device structures.

### BACKGROUND OF THE INVENTION

Complementary metal-oxide-semiconductor (CMOS) integrated circuits may integrate voltage controlled variable capacitance devices (i.e., varactors) in circuit designs for certain applications, such as radiofrequency (RF) communications and RF wireless applications. Varactors are particularly useful in oscillation circuits, such as voltage-controlled oscillators (VCOs), in which the varactor's tunability is used to tune the oscillation frequency of the circuit. Varactors find use in televisions, radios, computers, cellular phones, personal digital assistants, active filters, and other applications in which signals are synchronized.

The varactor consists of a MOS structure that includes a gate electrode, the semiconductor substrate, and a gate dielectric layer disposed between the substrate and gate electrode. The gate electrode and substrate form a capacitor/diode that is operated in negative and positive bias conditions. Because the varactor's capacitance can be tuned by adjusting the bias voltage, varactors can be characterized by a CV characteristic curve.

Although conventional CMOS varactors have been effective for their intended purpose, advances in varactor design are needed to optimize performance, such as the CV characteristic curve.

### SUMMARY OF THE INVENTION

The embodiments of the invention relate to a MOS varactor having an entire accumulation and depletion regime of its CV characteristic curve in one bias regime (negative or positive). This is accomplished without additional circuitry designed to shift the varactor's CV characteristic curve, as is required with conventional MOS varactors. In one embodiment of the invention, the MOS varactor may comprise a gate electrode, a well region of semiconductor material having a first conductivity type (e.g., p-type), contact regions to the well region that comprise heavily doped semiconductor material of the first conductivity type (e.g., p⁺-type), and a Schottky diode formed between the gate and contact regions. The Schottky diode may be formed by spacing the contact regions away from the gate electrode and siliciding the substrate surface. The gate electrode may be formed from semiconductor material of a second conductivity type (e.g., n-type) opposite to the first conductivity type. The gate electrode may be formed from semiconductor material of a second conductivity type (e.g., n-type) opposite to the first conductivity type, thus changing the flat band voltage of the MOS varactor and shifting accumulation and depletion regime of the CV characteristic curve in one bias regime, such as the negative bias regime.

Embodiments of the MOS varactor may be formed utilizing a CMOS n-channel FET polysilicon pre-doping process, which eliminates the need for a region of opposite polarity or conductivity type in the well adjacent to the gate electrode. Embodiment of the MOS varactor can be applied in BiCMOS technologies with an implanted subcollector or buried subcollector process derived from the bipolar device process. Embodiment of the MOS varactor can also be applied to a CMOS technology with a triple well integration that provides a junction isolated well region. In certain embodiments, the MOS varactor may operate as an accumulation varactor with the entire accumulation and depletion regime of the CV characteristic curve in negative gate bias.

### BRIEF DESCRIPTION OF THE DRAWINGS

The accompanying drawings, which are incorporated in and constitute a part of this specification, illustrate embodiments of the invention and, together with a general description of the invention given above and the detailed description of the embodiments given below, serve to explain the principles of the invention.

FIGS. 1-4 are diagrammatic cross-sectional views of a portion of a substrate at successive fabrication stages of a processing method in accordance with an embodiment of the invention.

### DETAILED DESCRIPTION

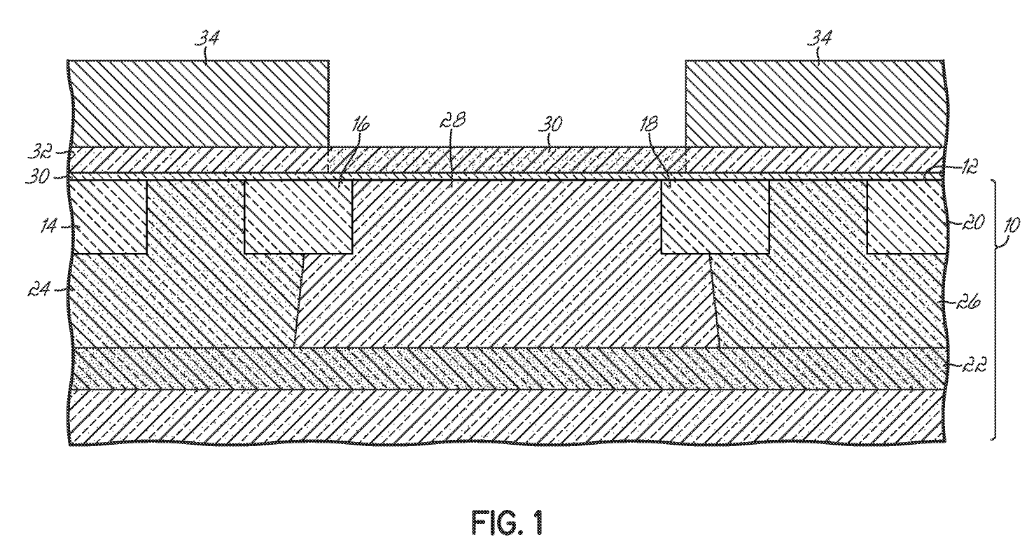

With reference to FIG. 1, a substrate 10 includes a top surface 12 and a plurality of isolation regions, of which isolation regions 14, 16, 18, 20 are representative. The substrate 10 may be made from a monocrystalline silicon-containing material, such as single crystal silicon with a (100), (110), or (111) crystal orientation. The semiconductor material constituting substrate 10 may be initially doped to impart a conductivity type. For example, the substrate 10 may be lightly doped with an n-type dopant species to render it initially n-type or lightly doped with a p-type dopant species to render it initially p-type. Alternatively, the substrate 10 may be formed from any other suitable semiconductor material including, but not limited to, such as gallium arsenide, germanium, silicon-germanium, indium phosphide, a silicon-on-insulator substrate (SOI), or a strained silicon substrate.

Each of the isolation structures 14, 16, 18, 20 consists of a respective trench with sidewalls extending from the top surface 12 into the substrate 10 and insulating or dielectric material filling the trench. The dielectric material contained in the isolation structures 14, 16, 18, 20 may comprise silicon oxide (SiO₂) or silicon nitride (Si₃N₄), and can be formed using shallow trench isolation (STI) techniques. For example, the trenches may be defined using standard lithography and anisotropic dry etching, filled with dielectric material, such as an oxide like densified tetraethylorthosilicate (TEOS) deposited by thermal chemical vapor deposition (CVD) or a high density plasma (HDP) oxide, and planarized by a conventional chemical mechanical polishing (CMP) process.

A doped isolation region 22 is defined in substrate 10 at a given depth beneath top surface 12 and deeper than the deepest extent of the isolation structures 14, 16, 18, 20 using any suitable ion implantation process. The implant may be a blanket implant so that isolation region 22 is continuous across the substrate 10 or a masked implant so that the isolation region 22 is local to vicinity of the isolation structures 14, 16, 18, 20. Heavily-doped well regions 24, 26 are defined in substrate 10 between isolation structures 14, 16 and isolation structures 18, 20, respectively, using any suitable ion implantation process. Another heavily-doped well region 28 is defined in substrate 10 between isolation structures 16, 18. The well regions 24, 26, 28 intersect the top surface 12 of the substrate 10. Following the implant processes, substrate 10 may be annealed to activate the isolation region 22 and the well regions 24, 26, 28. The conditions used to implant and activate the isolation region 22 and well regions 24, 26, 28 are well known to those skilled in the art.

The isolation region 22 and well regions 24, 26 have an opposite conductivity type to the substrate 10 and to well region 28. Regions 24, 26 provide conductive paths for contacting the isolation region 22 at top surface 22 as well as providing junction isolation for the well region 28 in the lateral dimension. Well region 28 has the same conductivity type as the substrate 10. Implant masks (not shown) are used to protect surface areas of top surface 12 during the individual implants of different conductivity type dopants. In one embodiment, the substrate 10 has a p-type conductivity, isolation region 22 contains a doping concentration of an n-type dopant sufficient to provide a net n-type conductivity in the p-type substrate 10, well regions 24, 26 constitute n-well regions containing a doping concentration of an n-type dopant sufficient to provide a net n-type conductivity in the p-type substrate 10, and well region 28 constitutes a p-well region with a higher doping concentration of the p-type dopant than the p-type substrate 10.

The isolation region 22 may be the product of a CMOS n-type isolation implant, a dedicated isolation implant, or a BiCMOS/Bipolar sub-collector process. Similarly, the well regions 24, 26 may be the product of a CMOS n-well implant or a BiCMOS/Bipolar reachthrough implant for sub-collector contacts that is common to bipolar transistor designs. The isolation region 22 and well regions 24, 26 may contain a concentration of an n-type dopant (e.g., antimony, phosphorus, or arsenic). Well region 28 may be the product of a CMOS p-well implant and, therefore, contain a concentration of a p-type dopant (e.g., boron, BF₂, indium, or gallium).

A thin gate dielectric layer 30 is formed on the top surface 12 of the substrate 10. Candidate dielectric materials for gate dielectric layer 30 include, but are not limited to, silicon oxynitride (SiOₓN_{y}), Si₃N₄, SiO₂, and layered stacks of these materials. In one embodiment, the gate dielectric layer 30 may be SiO₂ grown by exposing the semiconductor material of substrate 10 to either a dry oxygen ambient or steam in a heated environment.

A blanket layer 32 of a semiconductor material is deposited on the gate dielectric layer 30. The semiconductor layer 32 may comprise polycrystalline silicon (polysilicon) deposited using a known deposition process such as physical vapor deposition (PVD) or CVD using a silicon source gas like silane (SiH₄).

A patterned resist layer 34 is formed on the semiconductor layer 32 with openings defined to expose surface areas of the layer 32 at the subsequently-fabricated gate electrode locations. The patterned resist layer 34 may be formed by a conventional lithography process that involves applying a resist layer on semiconductor layer 32, exposing the applied resist to a pattern of radiation to create a latent pattern in the resist, and developing the latent pattern in the exposed resist to define the openings.

A region 36 of the semiconductor layer 32 overlying the well region 28 is doped with a concentration of a dopant having a conductivity type opposite to the conductivity type of the p-well region 28. The doped region 36 may be doped by an ion implantation process during which the patterned resist layer 34 protects adjacent regions of the semiconductor layer 32. The thickness of the patterned resist layer 34 is chosen to prevent dopant ions from being implanted into covered regions of the semiconductor layer 32 ultimately adjacent to doped region 36 when region 36 is doped. The doped region 36 may be formed during a typical CMOS process when the gate electrodes for the constituent field effect transistors (FETs), for example, the n-channel FETs, are doped. However, the doped region 36 is protected when other doping operations, such as implantations to define source/drain extensions and halos, in the CMOS process flow are performed.

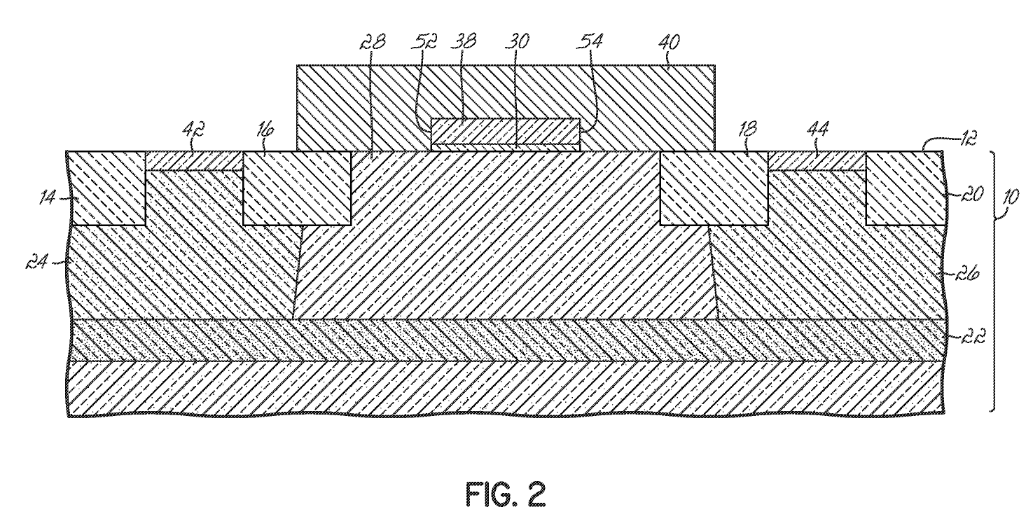

With reference to FIG. 2 in which like reference numerals refer to like features in FIG. 1 and at a subsequent fabrication stage, a gate electrode 38 is defined by an anisotropic dry etching process that transfers the pattern from the patterned resist layer 34 into the doped region 36 of semiconductor layer 32. The anisotropic dry etching process may be constituted by, for example, reactive ion etching (RIE), ion beam etching, or plasma etching using an etch chemistry that removes the constituent semiconductor material of semiconductor layer 32 selective to (i.e., with a significantly greater etch rate than) the dielectric material constituting the gate dielectric layer 30 and then an etch chemistry that removes the constituent dielectric material of gate dielectric layer 30 selective to the semiconductor material constituting the gate dielectric layer 30. Dielectric spacers (not shown) may be applied to sidewalls 52, 54 of the gate electrode 38 by a conventional spacer formation process.

The anisotropic dry etching process also trims the gate dielectric layer 30 to have similar dimensions as the gate electrode 38. The gate dielectric layer 30 physically separates and electrically isolates the gate electrode 38 from the well region 28.

A patterned resist layer 40 is then formed by a conventional lithography process on the top surface 12 of the semiconductor layer 32. The resist layer 40 covers a surface area of the substrate 10 between isolation structures 16, 18 including the gate electrode 38 and well region 28. Contact regions 42, 44 are defined between isolation structures 14, 16 and between isolation structures 18, 20, respectively, by doping the semiconductor material of substrate 10 with a concentration of a dopant having the same conductivity type as the well regions 24, 26, but with a higher doping concentration. Contact regions 42, 44 may be formed by, for example, an ion implantation process during which the resist layer 40 operates as an implant mask to protect the gate electrode 38. To that end, the thickness of the patterned resist layer 40 is chosen to prevent dopant ions from being implanted into the gate electrode 38 and well region 28 when contact regions 42, 44 are doped. In a typical CMOS process flow, the heavily doped contact regions 42, 44 may be formed when the source and drain regions of one type of FET, for example, the n-channel FETs, are formed. After etching is concluded, the resist layer 40 is stripped from the top surface 12 of the semiconductor layer 32 by, for example, plasma ashing or a chemical stripper as understood by a person having ordinary skill in the art.

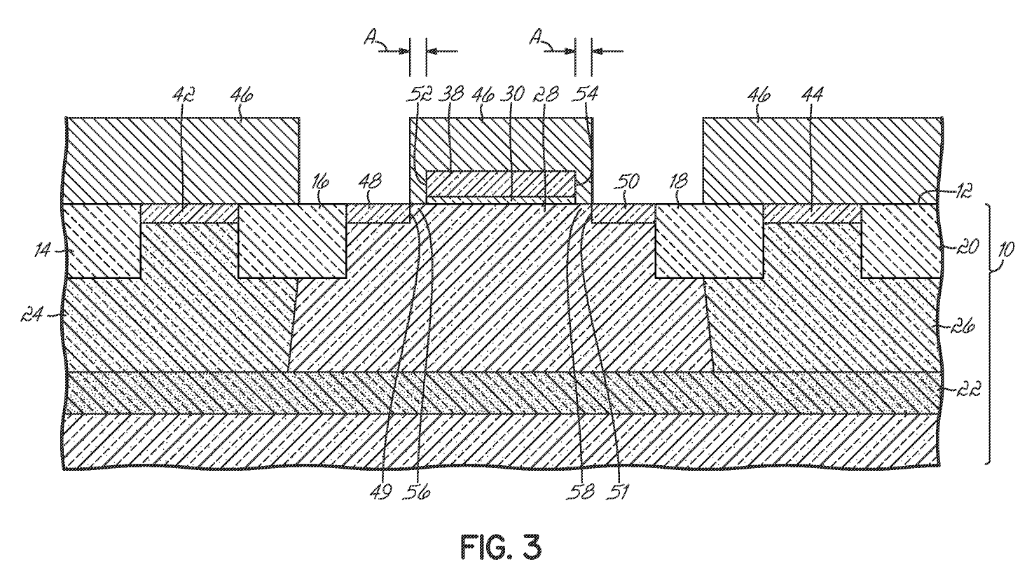

With reference to FIG. 3 in which like reference numerals refer to like features in FIG. 2 and at a subsequent fabrication stage, a patterned resist layer 46 is formed by a conventional lithography process on the top surface 12 of the substrate 10. The resist layer 46 exposes a portion of well region 28 adjacent to the isolation structures 16, 18, but covers the gate electrode 38 and the underlying portion of well region 28. Contact regions 48, 50 are defined in the semiconductor material of well region 28 that contain a concentration of a dopant having the same conductivity type as the well region 28, but with a higher doping concentration. As a result, the contact regions 48, 50 are contiguous with the well region 28 and adjacent to the gate electrode 38.

The contact regions 48, 50 may be formed by an ion implantation process during which the resist layer 46 operates as an implant mask to protect the gate electrode 38 and portions of well region 28 underlying and adjacent to the gate electrode 38. To that end, the thickness of the patterned resist layer 46 is chosen to prevent dopant ions from being implanted into the gate electrode 38 when contact regions 48, 50 are doped. In a typical CMOS process flow, the heavily doped contact regions 48, 50 may be formed when the source and drain regions of the other type of FET, for example, the p-channel FETs, are formed. The contact regions 48, 50 are used to contact the well region 28. After etching is concluded, the resist layer 46 is stripped from the top surface 12 of the semiconductor layer 32 by, for example, plasma ashing or a chemical stripper as understood by a person having ordinary skill in the art.

The resist layer 46 extends laterally of the sidewalls 52, 54 of gate electrode 38. As a result, the process doping the contact regions 48, 50 does not dope the semiconductor material of substrate 10 beneath a surface area, A, bounded between the vertical plane of sidewall 52 of the gate electrode 38 and a side edge 49 of contact area 48 and bounded between the vertical plane of sidewall 54 of the gate electrode 38 and a side edge 51 of contact area 50. Semiconducting regions 56, 58 of the well region 28 that do not receive additional dopant during the implantation are thus adjacent to the contact regions 48, 50, respectively, and separate the contact regions 48, 50 from the semiconductor material of the well region 28 underlying the gate electrode 38. Because the doping level or concentration of semiconducting regions 56, 58 of the well region 28 is not increased by the implantation, regions 56, 58 retain their semiconducting properties. Because of their relatively high doping concentration, contact regions 48, 50 are electrically conducting.

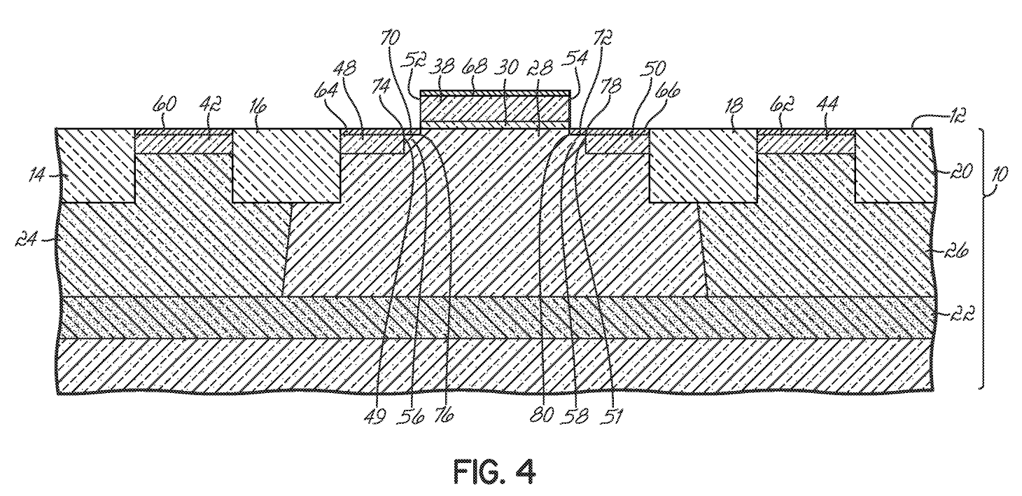

With reference to FIG. 4 in which like reference numerals refer to like features in FIG. 3 and at a subsequent fabrication stage, conducting regions 60, 62, 64, 66 comprising a material of low resistance (i.e., high conductivity) are formed on each of the contact regions 42, 44, 48, 50, respectively. Each of the conducting regions 60, 62, 64, 66 intersects the top surface 12 of substrate 10.

The conducting regions 60, 62, 64, 66 may comprise self-aligned silicide (i.e., salicide) including a silicide-forming metal, such as titanium (Ti), cobalt (Co), tungsten (W), or nickel (Ni), and formed using a conventional silicidation process familiar to a person having ordinary skill in the art. Generally, the silicidation process comprises depositing a layer of the silicide-forming metal over the contact regions 42, 44, 48, 50 and annealing at a high temperature in a controlled atmosphere to promote a reaction with the underlying semiconductor material to form a metal silicide. The metal silicide comprises silicon from the semiconductor material of contact regions 42, 44, 48, 50 and metal originating from the layer of silicide-forming metal. The silicide-forming metal can be deposited utilizing any deposition process known to those skilled in the art including, but are not limited to, PVD, CVD, and chemical solution deposition. Silicidation annealing conditions may vary contingent upon the type of silicide-forming metal, but are nevertheless familiar to a person having ordinary skill in the art. A similar conducting region 68 may be formed on a top surface of the gate electrode 38 concurrently with conducting regions 60, 62, 64, 66.

Each of the conducting regions 64, 66 includes a first area that shares a boundary with a respective one of the contact regions 48, 50 and a second area that shares a boundary with the masked surface area, A, overlying the well region 28 near the gate electrode 38 (FIG. 3). The conducting regions 64, 66 define Schottky junctions 70, 72, respectively, with the semiconducting regions 56, 58 of the well region 28 across the surface area, A, in which the conductor-semiconductor contact creates a potential barrier with rectifying characteristics. Consequently, conducting region 64 and semiconducting region 56 comprise a Schottky diode, as do conducting region 66 and semiconducting region 58.

The side edge 49 of contact region 48, which defines a boundary between contact region 48 and semiconducting region 56, further defines one peripheral edge 74 of Schottky junction 70. Conducting region 64 transitions at the side edge 49 from being contiguous with the heavily doped semiconductor material of contact region 48 to being continuous with semiconducting region 56. An opposite peripheral edge 76 of Schottky junction 70 is defined between peripheral edge 74 and the sidewall 52 of gate electrode 38. In the illustrated embodiment, peripheral edge 76 is defined at the edge of the conducting region 64 and, therefore, aligned with a vertical plane co-planar with sidewall 52 of gate electrode 38. However, the invention is not so limited as, for example, the sidewall 52 of gate electrode 38 may carry a dielectric spacer (not shown) that limits the proximity of the conducting region 64 on top surface 12 to sidewall 52.

Similarly, the side edge 51 of contact region 50, which defines a boundary between contact region 50 and semiconducting region 58, also defines one peripheral edge 78 of Schottky junction 72. Conducting region 66 transitions at the side edge 51 from being contiguous with the heavily doped semiconductor material of contact region 50 to being continuous with semiconducting region 58. An opposite peripheral edge 80 of Schottky junction 72 is defined between peripheral edge 78 and the sidewall 54 of gate electrode 38. In the illustrated embodiment, peripheral edge 80 is aligned with the edge of the conducting region 66 and, therefore, with a vertical plane co-planar with sidewall 54 of gate electrode 38. However, the invention is not so limited as, for example, the sidewall 54 of gate electrode 38 may carry a dielectric spacer (not shown) that limits the proximity of the conducting region 66 on top surface 12 to sidewall 54.

References herein to terms such as “vertical”, “horizontal”, etc. are made by way of example, and not by way of limitation, to establish a frame of reference. The term “horizontal” as used herein is defined as a plane parallel to a conventional plane of a semiconductor wafer or substrate, regardless of its actual three-dimensional spatial orientation. The term “vertical” refers to a direction perpendicular to the horizontal, as just defined. Terms, such as “on”, “above”, “below”, “side” (as in “sidewall”), “higher”, “lower”, “over”, “beneath” and “under”, are defined with respect to the horizontal plane. It is understood that various other frames of reference may be employed for describing the invention without departing from the spirit and scope of the invention. The term “on” used in the context of two layers means at least some contact between the layers. The term “over” means two layers that are in close proximity, but possibly with one or more additional intervening layers such that contact is possible, but not required. As used herein, neither “on” nor “over” implies any directionality.

The fabrication of the device structure herein has been described by a specific order of fabrication stages and steps. However, it is understood that the order may differ from that described. For example, the order of two or more fabrication steps may be switched relative to the order shown. Moreover, two or more fabrication steps may be conducted either concurrently or with partial concurrence. In addition, various fabrication steps may be omitted and other fabrication steps may be added. It is understood that all such variations are within the scope of the invention. It is also understood that features of the invention are not necessarily shown to scale in the drawings.

While the invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. Thus, the invention in its broader aspects is therefore not limited to the specific details, representative apparatus and method, and illustrative example shown and described. Accordingly, departures may be made from such details without departing from the spirit or scope of applicants' general inventive concept.

What is claimed is:

1. A device structure formed using a substrate of a semiconductor material having a top surface, the device structure comprising:
a well region defined in the substrate, said well region comprising the semiconductor material of the substrate doped to have a first conductivity type and containing a first doping concentration that retains semiconducting properties;
a gate electrode on the top surface of said well region, said gate electrode having a sidewall;
a dielectric layer separating the gate electrode from the well region;
a contact region contiguous with the well region and spaced from said sidewall of said gate electrode by an intervening portion of said well region, said contact region comprising semiconductor material doped to have the first conductivity type and containing a higher doping concentration than said intervening portion of said well region; and
a conducting region intersecting said top surface, said conducting region contiguous with said contact region to define an electrical contact and contiguous with said intervening portion of said well region to define a Schottky junction.

2. The device structure of claim 1 wherein the first conductivity type is p-type, and said gate electrode is formed from an n-type semiconductor material.

3. The device structure of claim 1 wherein said conducting region comprises a silicide including semiconductor material from said well and contact regions.

4. The device structure of claim 1 wherein said gate electrode comprises a semiconductor material having a second conductivity type opposite to the first conductivity type.

5. A method of making a device structure using a substrate of a semiconductor material having a top surface and a well region with a first conductivity type defined in the semiconductor material of the substrate, the method comprising:
forming a gate electrode carried on the top surface of the well region and in an electrically isolated relationship with the top surface of the well region;
forming a contact region in the semiconductor material of the well region that comprises semiconductor material of the first conductivity type with a higher doping concentration than the well region;
covering a surface area on the top surface of the well region adjacent to a sidewall of the gate electrode, when the contact region is formed, so that the semiconductor material of the well region beneath the covered surface area does not receive the higher doping concentration; and
forming a conducting region contiguous with the contact region to define an electrical contact and contiguous with the surface area of well region to define a Schottky junction positioned between the gate electrode and the contact region.

6. The method of claim 5 wherein forming the contact region further comprises:
implanting ions of the first conductivity type into the well region to form the contact region while preventing the implanted ions from entering the well region beneath the masked surface area.

7. The method of claim 5 wherein forming the conductive layer further comprising:
depositing a layer of a silicide-forming metal over the contact region and the surface area of well region; and
annealing at a temperature sufficient to form a metal silicide comprising silicon from the contact region and from the surface area of well region and metal from the layer of silicide-forming metal.
